(19) United States
(12) Patent Application Publication
(10) Pub. No.: US 2026/0155338 A1
(43) Pub. Date: Jun. 4, 2026

(54) ETCHING METHOD AND PLASMA PROCESSING APPARATUS

(71) Applicant: Tokyo Electron Limited, Tokyo (JP)

(72) Inventors: Shoi SUZUKI, Miyagi (JP); Aoi KITAGAWA, Miyagi (JP); Taku GOHIRA, Miyagi (JP)

(73) Assignee: Tokyo Electron Limited, Tokyo (JP)

(21) Appl. No.: 19/461,063

(22) Filed: Jan. 27, 2026

Related U.S. Application Data
(63) Continuation of application No. PCT/JP2024/026480, filed on Jul. 24, 2024.

(30) Foreign Application Priority Data
Aug. 7, 2023 (JP) 2023-128470

(51) Int. Cl. H01J 37/32

(52) U.S. Cl. CPC H01J 37/32495; H01J 37/32449; H01J 37/32467; H01J 37/32862; H01J 2237/0213; H01J 2237/022; H01J 2237/3341

(57) ABSTRACT

An etching method according to an example embodiment includes (a) supplying a film forming gas into a chamber through a gas feeding port of a showerhead containing silicon to form a protective film on an inner wall of the gas feeding port; and (b) supplying an etching gas into the chamber through the gas feeding port on which the protective film is formed to etch a substrate in the chamber with plasma generated from the etching gas.

### CROSS-REFERENCE TO RELATED APPLICATIONS

This application is a continuation application of PCT Application No. PCT/JP 2024/026480, filed on Jul. 24, 2024, which claims the benefit of priority from Japanese Patent Application No. 2023-128470, filed on Aug. 7, 2023. The entire contents of the above listed PCT and priority applications are incorporated herein by reference.

### BACKGROUND

### Field

Example embodiments of the present disclosure relate to an etching method and a plasma processing apparatus.

### Description of the Related Art

Japanese Unexamined Patent Publication No. 2009-188257 discloses a plasma etching method. This method includes a film forming step and an etching step. In the film forming step, a film forming gas containing carbon and fluorine is supplied into a processing container, and the film forming gas is converted into plasma to form a film containing carbon and fluorine in the processing container with the plasma. In the etching step, a substrate is placed on a placing table in a processing container, an etching gas is supplied into the processing container, and the etching gas is converted into plasma to etch the substrate with the plasma.

### SUMMARY

In one example embodiment, an etching method includes (a) supplying a film forming gas into a chamber through a gas feeding port of a showerhead containing silicon to form a protective film on an inner wall of the gas feeding port; and (b) supplying an etching gas into the chamber through the gas feeding port on which the protective film is formed to etch a substrate in the chamber with plasma generated from the etching gas.

### BRIEF DESCRIPTION OF THE DRAWINGS

FIG. 1 is a diagram for describing a configuration example of a plasma processing system.

FIG. 2 is a diagram illustrating a configuration example of a capacitively coupled plasma processing apparatus.

FIG. 3 is a flowchart illustrating an etching method according to an example embodiment.

FIG. 4 is an enlarged cross-sectional view of a showerhead during a step in an etching method according to an example embodiment.

FIG. 5 is an enlarged cross-sectional view of a showerhead during a step in an etching method according to an example embodiment.

FIG. 6 is an enlarged cross-sectional view of a showerhead during a step in an etching method according to an example embodiment.

FIG. 7 is an enlarged cross-sectional view of a showerhead during a step in an etching method according to an example embodiment.

FIG. 8 is a cross-sectional view of a plasma processing chamber according to a modification example.

FIG. 9 is a cross-sectional view of a plasma processing chamber according to another modification example.

### DETAILED DESCRIPTION

Hereinafter, various example embodiments will be described in detail with reference to the drawings. In the drawing, the same or equivalent portions are denoted by the same reference symbols.

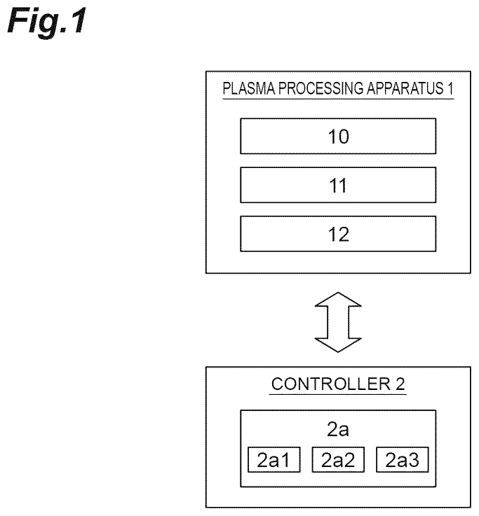

FIG. 1 illustrates an example configuration of a plasma processing system. In an embodiment, the plasma processing system includes a plasma processing apparatus 1 and a controller 2. The plasma processing system is an example substrate processing system, and the plasma processing apparatus 1 is an example substrate processing apparatus. The plasma processing apparatus 1 includes a plasma processing chamber 10, a substrate support 11, and a plasma generator 12. The plasma processing chamber 10 has a plasma processing space. The plasma processing chamber 10 further has at least one gas inlet for supplying at least one process gas into the plasma processing space and at least one gas outlet for exhausting gases from the plasma processing space. The gas inlet is connected to a gas supply 20 described below and the gas outlet is connected to a gas exhaust system 40 described below. The substrate support 11 is disposed in a plasma processing space and has a substrate supporting surface for supporting a substrate.

The plasma generator 12 is configured to generate a plasma from the at least one process gas supplied into the plasma processing space. The plasma formed in the plasma processing space may be, for example, a capacitively coupled plasma (CCP), an inductively coupled plasma (ICP), an electron-cyclotron-resonance (ECR) plasma, a helicon wave plasma (HWP), or a surface wave plasma (SWP). Various types of plasma generators may also be used, such as an alternating current (AC) plasma generator and a direct current (DC) plasma generator. In an embodiment, AC signal (AC power) used in the AC plasma generator has a frequency in a range of 100 kHz to 10 GHz. Hence, examples of the AC signal include a radio frequency (RF) signal and a microwave signal. In an embodiment, the RF signal has a frequency in a range of 100 kHz to 150 MHz.

The controller 2 processes computer executable instructions causing the plasma processing apparatus 1 to perform various steps described in this disclosure. The controller 2 may be configured to control individual components of the plasma processing apparatus 1 such that these components execute the various steps. In an embodiment, the functions of the controller 2 may be partially or entirely incorporated into the plasma processing apparatus 1. The controller 2 may include a processor 2a 1, a storage 2a2, and a communication interface 2a3. The controller 2 is implemented in, for example, a computer 2a. The processor 2a1 may be configured to read a program from the storage 2a2, and then perform various controlling operations by executing the program. This program may be preliminarily stored in the storage 2a2 or retrieved from any medium, as appropriate. The resulting program is stored in the storage 2a2, and then the processor 2a1 reads to execute the program from the storage 2a2. The medium may be of any type which can be accessed by the computer 2a or may be a communication line connected to the communication interface 2a3. The processor 2a1 may be a central processing unit (CPU). The storage 2a2 may include a random access memory (RAM), a read only memory (ROM), a hard disk drive (HDD), a solid state drive (SSD), or any combination thereof. The communication interface 2a3 can communicate with the plasma processing apparatus 1 via a communication line, such as a local area network (LAN).

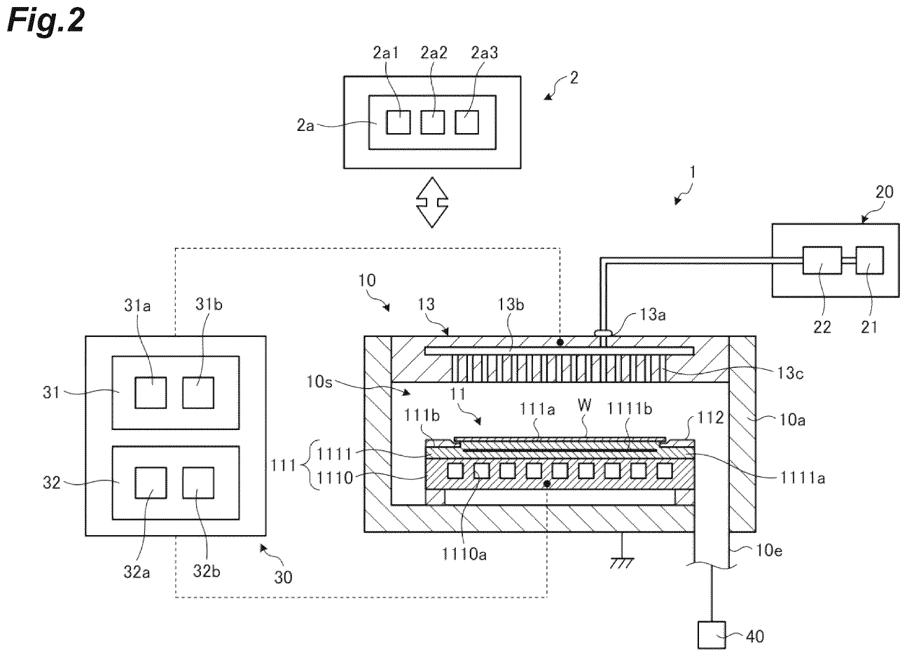

An example configuration of a capacitively coupled plasma processing apparatus, which is an example of the plasma processing apparatus 1, will now be described. FIG. 2 illustrates the example configuration of the capacitively coupled plasma processing apparatus.

The capacitively coupled plasma processing apparatus 1 includes a plasma processing chamber 10, a gas supply 20, an electric power source 30, and a gas exhaust system 40. The plasma processing apparatus 1 further includes a substrate support 11 and a gas introduction unit. The gas introduction unit is configured to introduce at least one process gas into the plasma processing chamber 10. The gas introduction unit includes a showerhead 13. The substrate support 11 is disposed in a plasma processing chamber 10. The showerhead 13 is disposed above the substrate support 11. In an embodiment, the showerhead 13 functions as at least part of the ceiling of the plasma processing chamber 10. The plasma processing chamber 10 has a plasma processing space 10s that is defined by the showerhead 13, the sidewall 10a of the plasma processing chamber 10, and the substrate support 11. The plasma processing chamber 10 is grounded. The showerhead 13 and the substrate support 11 are electrically insulated from the housing of the plasma processing chamber 10.

The substrate support 11 includes a body 111 and a ring assembly 112. The body 111 has a central region 111a for supporting a substrate W and an annular region 111b for supporting the ring assembly 112. An example of the substrate W is a wafer. The annular region 111b of the body 111 surrounds the central region 111a of the body 111 in plan view. The substrate W is disposed on the central region 111a of the body 111, and the ring assembly 112 is disposed on the annular region 111b of the body 111 so as to surround the substrate W on the central region 111a of the body 111. Thus, the central region 111a is also called a substrate supporting surface for supporting the substrate W, while the annular region 111b is also called a ring supporting surface for supporting the ring assembly 112.

In an embodiment, the body 111 includes a base 1110 and an electrostatic chuck 1111. The base 1110 includes a conductive member. The conductive member of the base 1110 can function as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the central region 111a. In an embodiment, the ceramic member 1111a also has the annular region 111b. Any other member, such as an annular electrostatic chuck or an annular insulting member, surrounding the electrostatic chuck 1111 may have the annular region 111b. In this case, the ring assembly 112 may be disposed on either the annular electrostatic chuck or the annular insulating member, or both the electrostatic chuck 1111 and the annular insulating member. At least one RF/DC electrode coupled to an RF source 31 and/or a DC source 32 described below may be disposed in the ceramic member 1111a. In this case, the at least one RF/DC electrode functions as the lower electrode. If a bias RF signal and/or DC signal described below are supplied to the at least one RF/DC electrode, the RF/DC electrode is also called a bias electrode. It is noted that the conductive member of the base 1110 and the at least one RF/DC electrode may each function as a lower electrode. The electrostatic electrode 1111b may also be function as a lower electrode. The substrate support 11 accordingly includes at least one lower electrode.

The ring assembly 112 includes one or more annular members. In an embodiment, the annular members include one or more edge rings and at least one cover ring. The edge ring is composed of a conductive or insulating material, whereas the cover ring is composed of an insulating material.

The substrate support 11 may also include a temperature adjusting module that is configured to adjust at least one of the electrostatic chuck 1111, the ring assembly 112, and the substrate to a target temperature. The temperature adjusting module may be a heater, a heat transfer medium, a flow passage 1110a, or any combination thereof. A heat transfer fluid, such as brine or gas, flows into the flow passage 1110a. In an embodiment, the flow passage 1110a is formed in the base 1110, one or more heaters are disposed in the ceramic member 1111a of the electrostatic chuck 1111. The substrate support 11 may further include a heat transfer gas supply configured to supply a heat transfer gas to a gap between the rear surface of the substrate W and the central region 111a.

The showerhead 13 is configured to introduce at least one process gas from the gas supply 20 into the plasma processing space 10s. The showerhead 13 has at least one gas inlet 13a, at least one gas diffusing space 13b, and a plurality of gas feeding ports 13c. The process gas supplied to the gas inlet 13a passes through the gas diffusing space 13b and is then introduced into the plasma processing space 10s from the gas feeding ports 13c. The showerhead 13 further includes at least one upper electrode. The gas introduction unit may include one or more side gas injectors provided at one or more openings formed in the sidewall 10a, in addition to the showerhead 13.

The gas supply 20 may include at least one gas source 21 and at least one flow controller 22. In an embodiment, the gas supply 20 is configured to supply at least one process gas from the corresponding gas source 21 through the corresponding flow controller 22 into the showerhead 13. Each flow controller 22 may be, for example, a mass flow controller or a pressure-controlled flow controller. The gas supply 20 may include a flow modulation device that can modulate or pulse the flow of the at least one process gas.

The electric power source 30 include an RF source 31 coupled to the plasma processing chamber 10 through at least one impedance matching circuit. The RF source 31 is configured to supply at least one RF signal (RF power) to at least one lower electrode and/or at least one upper electrode. A plasma is thereby formed from at least one process gas supplied into the plasma processing space 10s. Thus, the RF source 31 can function as at least part of the plasma generator 12. The bias RF signal supplied to the at least one lower electrode causes a bias potential to occur in the substrate W, which potential then attracts ionic components in the plasma to the substrate W.

In an embodiment, the RF source 31 includes a first RF generator 31a and a second RF generator 31b. The first RF generator 31a is coupled to the at least one lower electrode and/or the at least one upper electrode through the at least one impedance matching circuit and is configured to generate a source RF signal (source RF power) for generating a plasma. In an embodiment, the source RF signal has a frequency in a range of 10 MHz to 150 MHz. In an embodiment, the first RF generator 31a may be configured to generate two or more source RF signals having different frequencies. The resulting source RF signal(s) is supplied to the at least one lower electrode and/or the at least one upper electrode.

The second RF generator 31b is coupled to the at least one lower electrode through the at least one impedance matching circuit and is configured to generate a bias RF signal (bias RF power). The bias RF signal and the source RF signal may have the same frequency or different frequencies. In an embodiment, the bias RF signal has a frequency which is less than that of the source RF signal. In an embodiment, the bias RF signal has a frequency in a range of 100 kHz to 60 MHz. In an embodiment, the second RF generator 31 b may be configured to generate two or more bias RF signals having different frequencies. The resulting bias RF signal(s) is supplied to the at least one lower electrode. In various embodiments, at least one of the source RF signal and the bias RF signal may be pulsed.

The electric power source 30 may also include a DC source 32 coupled to the plasma processing chamber 10. The DC source 32 includes a first DC generator 32a and a second DC generator 32b. In an embodiment, the first DC generator 32a is connected to the at least one lower electrode and is configured to generate a first DC signal. The resulting first DC signal is applied to the at least one lower electrode. In an embodiment, the second DC generator 32b is connected to the at least one upper electrode and is configured to generate a second DC signal. The resulting second DC signal is applied to the at least one upper electrode.

In various embodiments, the first and second DC signals may be pulsed. In this case, a sequence of voltage pulses is applied to the at least one lower electrode and/or the at least one upper electrode. The voltage pulses have rectangular, trapezoidal, or triangular waveform, or a combined waveform thereof. In an embodiment, a waveform generator for generating a sequence of voltage pulses from the DC signal is disposed between the first DC generator 32a and the at least one lower electrode. The first DC generator 32a and the waveform generator thereby functions as a voltage pulse generator. In the case that the second DC generator 32b and the waveform generator functions as a voltage pulse generator, the voltage pulse generator is connected to the at least one upper electrode. The voltage pulse may have positive polarity or negative polarity. A sequence of voltage pulses may also include one or more positive voltage pulses and one or more negative voltage pulses in a cycle. The first and second DC generators 32a, 32b may be disposed in addition to the RF source 31, or the first DC generator 32a may be disposed in place of the second RF generator 31b.

The gas exhaust system 40 may be connected to, for example, a gas outlet 10e provided in the bottom wall of the plasma processing chamber 10. The gas exhaust system 40 may include a pressure regulation valve and a vacuum pump. The pressure regulation valve enables the pressure in the plasma processing space 10s to be adjusted. The vacuum pump may be a turbo-molecular pump, a dry pump, or a combination thereof.

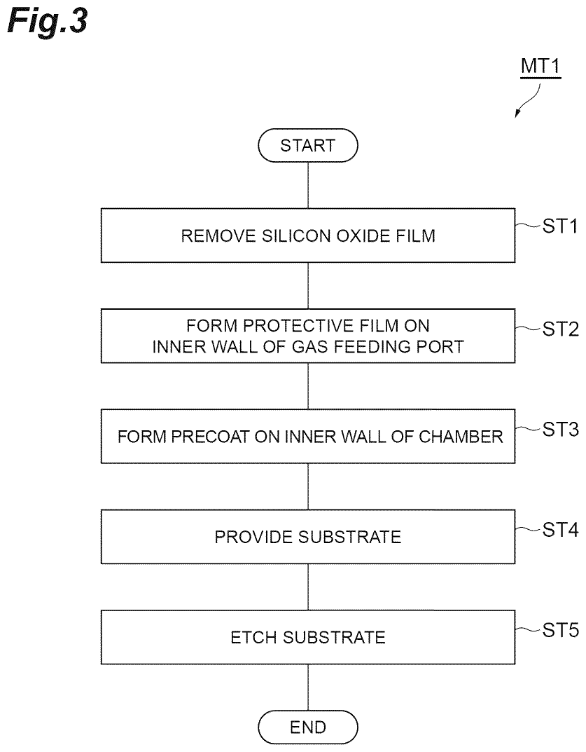

FIG. 3 is a flowchart illustrating an etching method according to an example embodiment. An etching method MT1 (referred to as a “method MT1” below) illustrated in FIG. 3 can be performed by the plasma processing apparatus 1 in the above embodiment.

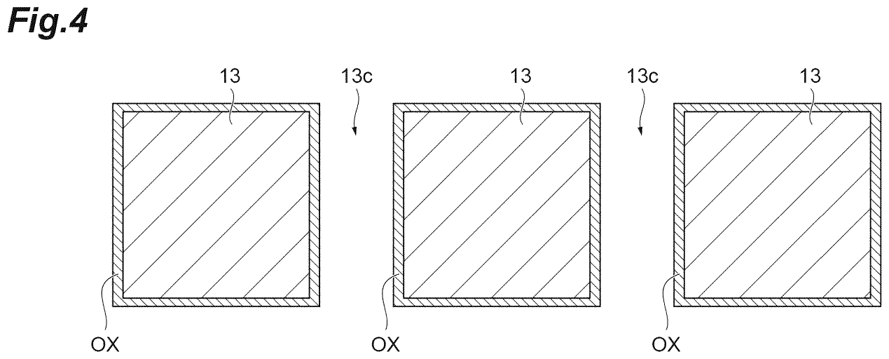

The method MT1 will be described with reference to FIGS. 2 to 7 by using, as an example, the case where the method MT1 is applied to the substrate W by using the plasma processing apparatus 1 in the above-described embodiment. FIGS. 4 to 7 are enlarged cross-sectional views of a showerhead during steps of an etching method according to an example embodiment. When the plasma processing apparatus 1 is used, the method MT1 can be performed in the plasma processing apparatus 1 in a manner that the controller 2 controls each unit of the plasma processing apparatus 1. In the method MT1, as illustrated in FIG. 2, the substrate W on the substrate support 11 disposed in the plasma processing chamber 10 is processed.

As illustrated in FIG. 3, the method MT1 may include steps ST1 to ST5. Steps ST1 to ST5 can be performed in order. The method MT1 may not include at least one of steps ST1, ST3, and ST4. Step ST3 may be performed before step ST2. Step ST4 may be performed before step ST3, before step ST2, or before step ST1.

### Step ST1

As illustrated in FIG. 4, a silicon oxide film OX formed on the surface of the showerhead 13 of the plasma processing apparatus 1 is removed. The showerhead 13 contains silicon. The showerhead 13 may contain crystalline silicon. The silicon oxide film OX may be a native oxide film. The silicon oxide film OX may be removed by an etching gas such as a hydrogen fluoride gas.

The etching gas may be supplied into the plasma processing chamber 10 from the gas supply 20 (see FIG. 2) through the gas feeding port 13c of the showerhead 13. The supply of the etching gas may be stopped at the end of Step ST1. In Step ST1, the plasma may not be generated in the plasma processing chamber 10. In Step ST1, the substrate W may not be placed on the substrate support 11 (see FIG. 2), or a dummy substrate different from the substrate W may be placed thereon.

Step ST1 may be performed as follows. The gas supply 20 supplies the etching gas into the plasma processing chamber 10. The controller 2 controls the gas supply 20 and the plasma generator 12 such that plasma is not generated.

### Step ST2

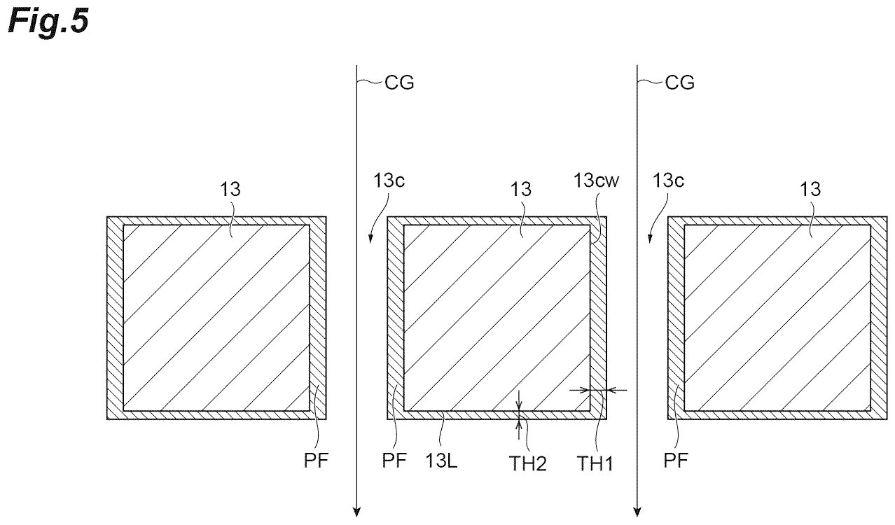

As illustrated in FIG. 5, a film forming gas CG is supplied into the plasma processing chamber 10 through the gas feeding port 13c of the showerhead 13, and a protective film PF is formed on an inner wall 13cw of the gas feeding port 13c.

The film forming gas CG may be supplied into the plasma processing chamber 10 from the gas supply 20 through the gas feeding port 13c of the showerhead 13. The supply of the film forming gas CG may be stopped at the end of Step ST2. In Step ST2, the substrate W may not be placed on the substrate support 11, or a dummy substrate different from the substrate W may be placed thereon.

The film forming gas CG may contain a metal. The film forming gas CG may contain a metal fluoride gas. The metal fluoride gas may contain at least one selected from the group consisting of a tungsten hexafluoride (WF₆) gas and a molybdenum hexafluoride (MoF₆) gas. The film forming gas CG may further contain a reducing gas such as hydrogen (H₂) gas. The film forming gas CG may further contain a noble gas such as argon (Ar) gas. The film forming gas CG may further contain an oxygen-containing gas such as an oxygen (O₂) gas. The oxygen-containing gas can form an oxide film as the protective film PF. Examples of the oxide film include a metal oxide film. The film forming gas CG may not contain a halogen-containing gas different from the metal fluoride gas.

The flow rate of the film forming gas CG may be greater than the flow rate of an etching gas EG in Step ST5. Accordingly, the thickness of the protective film PF can be increased. The flow rate of the metal fluoride gas contained in the film forming gas CG may be greater than the flow rate of the metal fluoride gas contained in the etching gas EG.

The protective film PF may contain a metal. The metal may contain at least one selected from the group consisting of tungsten and molybdenum. When the film forming gas CG contains tungsten, the protective film PF contains tungsten. When the film forming gas CG contains molybdenum, the protective film PF contains molybdenum.

The protective film PF may be formed on a lower surface 13L of the showerhead 13. The showerhead 13 can constitute at least a part of the ceiling of the plasma processing chamber 10. Therefore, the lower surface 13L faces a plasma processing space 10s of the plasma processing chamber 10. Therefore, the lower surface 13L can be exposed to plasma generated in the plasma processing chamber 10. The protective film PF may be formed on a region (for example, an inner wall of a gas diffusing space 13b illustrated in FIG. 2) of the surface of the showerhead 13 excluding the inner wall 13cw of the gas feeding port 13c and the lower surface 13L. The protective film PF may be formed on the surface of a silicon-containing member different from the showerhead 13. The silicon-containing member can constitute at least a part of the plasma processing chamber 10. By setting the temperature of the silicon-containing member to be lower than the temperature of the showerhead 13, the protective film PF can be selectively formed on the surface of the showerhead 13 without forming the protective film PF on the surface of the silicon-containing member.

The protective film PF may have a thickness of 100 nm or more and 10 μm or less. The protective film PF may have a first thickness TH1 on the inner wall 13cw of the gas feeding port 13c. The protective film PF may have a second thickness TH2 on the lower surface 13L of the showerhead 13. The second thickness TH2 is smaller than the first thickness TH1.

In Step ST2, plasma may not be generated in the plasma processing chamber 10, or plasma may be generated from the film forming gas CG.

The temperature of the showerhead 13 in Step ST2 may be higher than the temperature of the showerhead 13 in Step ST5. The temperature of the showerhead 13 in Step ST2 may be 200° C. or higher or 300° C. or higher. The temperature of the showerhead 13 in Step ST2 may be 800° C. or lower. The temperature of the showerhead 13 may be adjusted by a temperature adjusting module included in the plasma processing apparatus 1. Alternatively, in the plasma processing chamber 10, the showerhead 13 may be heated by the plasma generated from a process gas containing a noble gas.

Step ST2 may be performed as follows. The gas supply 20 supplies the film forming gas CG into the plasma processing chamber 10. The controller 2 controls the gas supply 20 and the plasma generator 12 such that no plasma is generated and the protective film PF is formed on the inner wall 13cw of the gas feeding port 13c.

### Step ST3

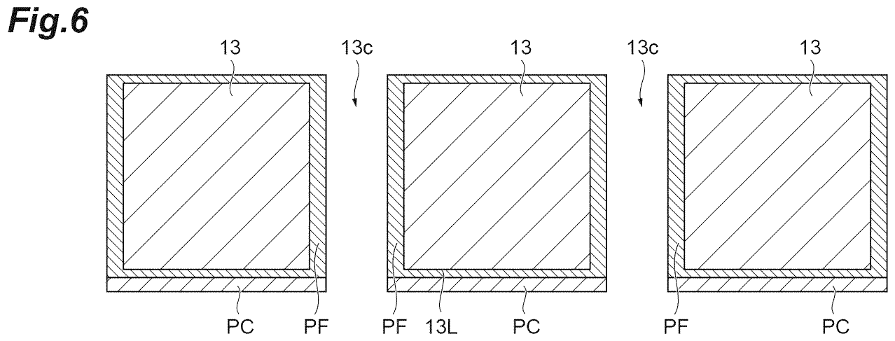

As illustrated in FIG. 6, a precoat PC is formed on the inner

wall of the plasma processing chamber 10. The inner wall of the plasma processing chamber 10 includes the lower surface 13L of the showerhead 13 and a sidewall 10a (see FIG. 2) of the plasma processing chamber 10. Therefore, the precoat PC is formed on the lower surface 13L of the showerhead 13 and the sidewall 10a of the plasma processing chamber 10. When Step ST3 is performed after Step ST2, the precoat PC can be formed on the protective film PF. The precoat PC is formed on the protective film PF on the lower surface 13L of the showerhead 13. The precoat PC may be formed on the protective film PF in the inner wall 13cw of the gas feeding port 13c. When Step ST2 is performed after Step ST3, the protective film PF can be formed on the precoat PC.

The film forming gas for the precoat PC may be supplied into the plasma processing chamber 10 from the gas supply 20 through the gas feeding port 13c of the showerhead 13. The supply of the film forming gas may be stopped at the end of Step ST3. In Step ST3, the substrate W may not be placed on the substrate support 11, or a dummy substrate different from the substrate W may be placed thereon.

The film forming gas for the precoat PC may contain a carbon-containing gas. The film forming gas may be a gas containing no fluorine. The carbon-containing gas may contain one or more selected from the group consisting of CO, CO₂, COS, and a hydrocarbon. The hydrocarbon may be CH₄, C₂H₂, C₃H₆, or the like. The precoat PC may be formed by a chemical vapor deposition (CVD) method, a molecular layer deposition (MLD) method, or an atomic layer deposition (ALD) method. In Step ST3, the plasma may be generated from the film forming gas in the plasma processing chamber 10.

The precoat PC may contain carbon. The precoat PC may have a thickness greater than the thickness of the protective film PF formed in Step ST2. The precoat PC has high plasma resistance.

Step ST3 may be performed as follows. The gas supply 20 supplies a film forming gas for the precoat PC into the plasma processing chamber 10. The controller 2 controls the gas supply 20 and the plasma generator 12 such that the precoat PC is formed on the inner wall of the plasma processing chamber 10.

### Step ST4

As illustrated in FIG. 2, the substrate W is provided in the plasma processing chamber 10. The substrate W may be transported from outside the plasma processing chamber 10 into the plasma processing chamber 10 by a transport mechanism. The substrate W can be placed on the substrate support 11. When the dummy substrate is placed on the substrate support 11 in Steps ST1 to ST3, the dummy substrate is transported outside the plasma processing chamber 10 before Step ST4.

### Step ST5

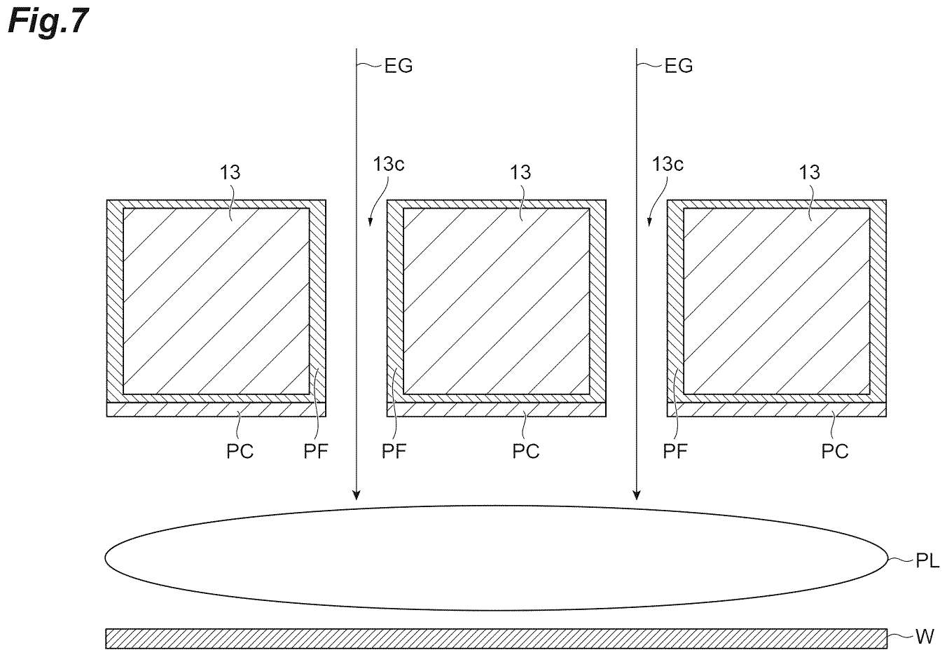

As illustrated in FIG. 7, the etching gas EG is supplied into the plasma processing chamber 10 through the gas feeding port 13c on which the protective film PF is formed, and the substrate W in the plasma processing chamber 10 is etched by the plasma PL generated from the etching gas EG. In Step ST5, a film to be etched, which is included in the substrate W, may be etched. The film to be etched may be a silicon-containing film.

The etching gas EG may be supplied into the plasma processing chamber 10 from the gas supply 20 through the gas feeding port 13c of the showerhead 13. The supply of the etching gas EG may be stopped at the end of Step ST5.

The etching gas EG may be the same as or different from the film forming gas CG in Step ST2. The etching gas EG may contain the same gas as the film forming gas CG. The etching gas EG may contain a metal fluoride gas. The metal fluoride gas may contain at least one selected from the group consisting of a tungsten hexafluoride gas and a molybdenum hexafluoride gas. The etching gas EG may further contain a fluorine-containing gas different from the metal fluoride gas. The fluorine-containing gas may contain at least one selected from the group consisting of a fluorocarbon gas, a hydrofluorocarbon gas, and a hydrogen fluoride gas.

The etching gas EG may contain a fluorine-containing gas which is a fluorine source and a hydrogen-containing gas which is a hydrogen source. The etching gas EG may contain one or more of H₂, CH₄, CH₂F₂, CH₃F, CHF₃, H₂O, HF, HCl, HBr, HI, and the like as a hydrogen source. The etching gas EG may contain one or more of CF₄, C₄F₈, C₄F₆, C₃F₈, C₅F₈, SF₆, NF₃, XeF₂, PF₃, PF₅, CF₃I, C₂F₅I, C₃F₇I, IF₅, IF₇, WF₆, HF, SiF₄, and the like as a fluorine source.

The etching gas EG may further contain one or more phosphorus-containing molecules. The one or more phosphorus-containing molecules may contain an oxide such as tetraphosphorus decoxide (P₄O₁₀), tetraphosphorus octoxide (P₄O₈), or tetraphosphorus hexoxide (P₄O₆). The tetraphosphorus decoxide may be referred to as diphosphorus pentoxide (P₂O₅). The one or more phosphorus-containing molecules may contain a halide such as phosphorus trifluoride (PF₃), phosphorus pentafluoride (PF₅), phosphorus trichloride (PCl₃), phosphorus pentachloride (PCl₅), phosphorus tribromide (PBr₃), phosphorus pentabromide (PBr₅), or phosphorus iodide (PI₃). The one or more phosphorus-containing molecules may contain a phosphoryl halide such as phosphoryl fluoride (POF₃), phosphoryl chloride (POCl₃), or phosphoryl bromide (POBr₃). The one or more phosphorus-containing molecules may contain phosphine (PH₃), calcium phosphide (Ca₃P₂ or the like), phosphoric acid (H₃PO₄), sodium phosphate (Na₃PO₄), hexafluorophosphate (HPF₆), and the like. The one or more phosphorus-containing molecules may contain fluorophosphines (HₓPF_{y}). Here, the sum of x and y is 3 or 5. Examples of the fluorophosphines include HPF₂ and H₂PF₃.

The temperature of the showerhead 13 in Step ST5 may be less than 200° C. or may be 150° C. or lower. The temperature of the showerhead 13 in Step ST5 may be −20° C. or higher.

Step ST5 may be performed as follows. The gas supply 20 supplies the etching gas EG into the plasma processing chamber 10. The controller 2 controls the gas supply 20 and the plasma generator 12 such that the plasma PL is generated from the etching gas EG and the substrate W is etched.

According to the method MT1, in Step ST2, the inner wall 13cw of the gas feeding port 13c can be protected by the protective film PF. Therefore, in Step ST5, corrosion of the inner wall 13cw of the gas feeding port 13c by the etching gas EG can be suppressed. When the film forming gas CG contains a tungsten hexafluoride gas in Step ST2, the tungsten hexafluoride reacts with silicon contained in the showerhead 13 to generate tungsten and silicon tetrafluoride (SiF₄). As a result, a tungsten film can be formed as the protective film PF.

In the method MT1, Step ST4 may be performed between Step ST3 and Step ST5. In this case, it is possible to suppress the substrate W from being exposed to the film forming gas in Steps ST2 and ST3. Accordingly, it is possible to suppress the formation of an unintended film on the substrate W by the film forming gas.

In the method MT1, the temperature of the showerhead 13 in Step ST2 may be higher than the temperature of the showerhead 13 in Step ST5. In this case, formation of the protective film PF is promoted in Step ST2, but the protective film PF is difficult to remove in Step ST5.

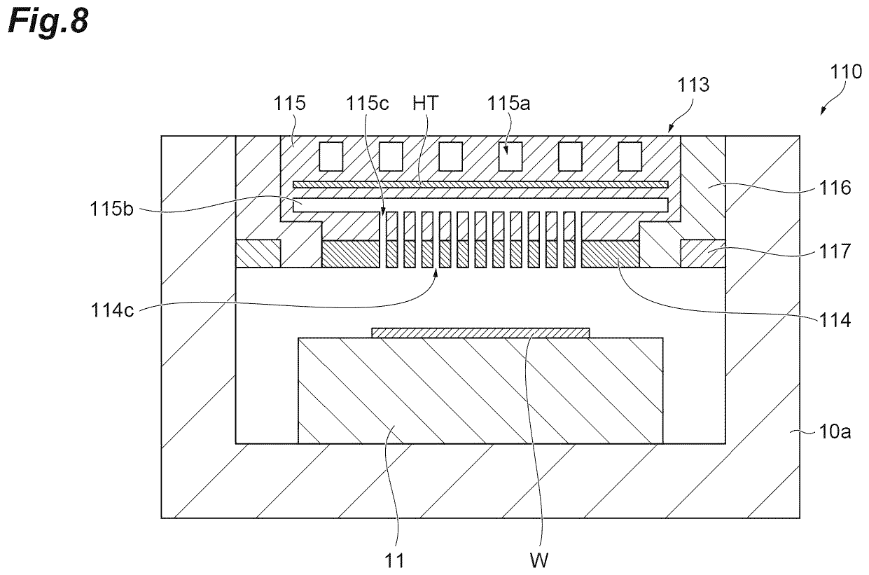

FIG. 8 is a cross-sectional view of a plasma processing chamber according to a modification example. The plasma processing chamber 10 of the plasma processing apparatus 1 illustrated in FIG. 2 may be replaced with a plasma processing chamber 110 of FIG. 8. The plasma processing chamber 110 of FIG. 8 has the same configuration as the plasma processing chamber 10 except that a showerhead 113 is provided instead of the showerhead 13.

The showerhead 113 may include a top plate 114 containing silicon, a temperature adjusting module 115, a support member 116 containing an insulator, and a member 117 containing silicon.

The top plate 114 may be an upper electrode. The lower surface of the showerhead 113 (the top plate 114) faces the plasma processing space 10s. The top plate 114 has a plurality of gas feeding ports 114c.

The temperature adjusting module 115 is provided on the top plate 114 and is configured to adjust the temperature of the top plate 114. The temperature adjusting module 115 includes a flow passage 115a for flowing a cooling fluid that cools the top plate 114, and a heater HT for heating the top plate 114. An inlet and an outlet of the flow passage 115a are connected to a chiller unit outside the plasma processing chamber 110. The temperature adjusting module 115 may include a mechanism that discharges the cooling fluid in the flow passage 115a by gas during heating by the heater HT. The temperature adjusting module 115 includes a gas diffusing space 115b and a plurality of gas feeding ports 115c communicating with the gas diffusing space 115b. The gas diffusing space 115b is connected to the gas supply 20 (see FIG. 2) via a gas supply passage. The plurality of gas feeding ports 115c communicate with the plurality of gas feeding ports 114c, respectively. The flow passage 115a, the heater HT, the gas diffusing space 115b, and the plurality of gas feeding ports 115c may be disposed in the main body of the temperature adjusting module 115. The main body of the temperature adjusting module 115 includes a metal such as aluminum. The heater HT may be disposed between the flow passage 115a and the gas diffusing space 115b. The process gas supplied from the gas supply 20 is supplied to the gas diffusing space 115b, passes through the plurality of gas feeding ports 115c, and is introduced into the plasma processing chamber 110 from the plurality of gas feeding ports 114c.

The support member 116 supports the temperature adjusting module 115. The support member 116 is connected to the sidewall 10a of the plasma processing chamber 110. The member 117 containing silicon is disposed between the support member 116 and the sidewall 10a. The member 117 containing silicon can be grounded by the sidewall 10a.

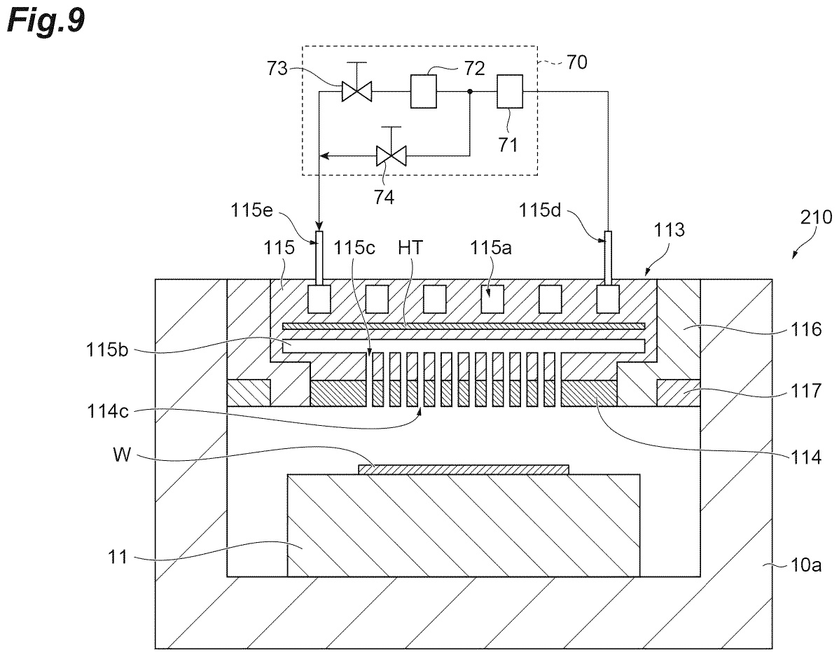

FIG. 9 is a cross-sectional view of a plasma processing chamber according to another modification example. The plasma processing chamber 10 of the plasma processing apparatus 1 illustrated in FIG. 2 may be replaced with a plasma processing chamber 210 of FIG. 9. The plasma processing chamber 210 of FIG. 9 has the same configuration as the plasma processing chamber 110 except that a chiller unit 70 is further provided.

An output port of the chiller unit 70 is connected to an inlet 115e of the flow passage 115a. A return port of the chiller unit 70 is connected to an outlet 115d of the flow passage 115a. The chiller unit 70 outputs a cooling fluid from the output port and supplies the cooling fluid from the inlet 115e to the flow passage 115a. The cooling fluid supplied to the flow passage 115a is returned to the chiller unit 70 via the outlet 115d and the return port. That is, the cooling fluid is circulated between the flow passage 115a and the chiller unit 70.

The chiller unit 70 is a direct expansion type chiller unit. The chiller unit 70 has a compressor 71, a condenser 72, and an expansion valve 73. The compressor 71, the condenser 72, and the expansion valve 73 are connected in order between the outlet 115d and the inlet 115e of the flow passage 115a. The top plate 114 constitutes an evaporator. The input of the compressor 71 is connected to the outlet 115d of the flow passage 115a via the return port of the chiller unit 70. The output of the compressor 71 is connected to the input of the condenser 72. The output of the condenser 72 is connected to the input of the expansion valve 73. The output of the expansion valve 73 is connected to the inlet 115e of the flow passage 115a via the output port of the chiller unit 70.

The cooling fluid output from the outlet 115d of the flow passage 115a is returned to the input of the compressor 71 and is compressed by the compressor 71. The high-pressure cooling fluid output from the compressor 71 is cooled and is liquefied by the condenser 72. The liquid cooling fluid output from the condenser 72 is decompressed in the expansion valve 73. The cooling fluid supplied from the expansion valve 73 to the flow passage 115a is vaporized by absorbing heat from the top plate 114. Then, the cooling fluid output from the flow passage 115a is returned to the input of the compressor 71 again. An opening degree of the expansion valve 73 is variable. As the opening degree of the expansion valve 73 is lower, the pressure of the cooling fluid is lower and the temperature at which the cooling fluid is vaporized is lower. Therefore, the temperature of the top plate 114 can be cooled to a lower temperature.

The chiller unit 70 further has a flow dividing valve 74. The flow dividing valve 74 is connected to bypass the condenser 72 and the expansion valve 73 between the compressor 71 and the inlet 115e of the flow passage 115a. That is, the input of the flow dividing valve 74 is connected to the output of the compressor 71. In addition, the output of the flow dividing valve 74 is connected to the inlet 115e of the flow passage 115a. An opening degree of the flow dividing valve 74 is variable. As the opening degree of the flow dividing valve 74 increases, a dryness degree of the cooling fluid supplied to the flow passage 115a increases. As the dryness degree increases, a heat extraction capability of the cooling fluid decreases. Therefore, the top plate 114 can be heated by opening the flow dividing valve 74.

In the plasma processing chambers 110 and 210 illustrated in FIGS. 8 and 9, the top plate 114 of the showerhead 113 can also be heated or cooled.

Although the various example embodiments have been described above, various omissions, substitutions, and changes may be made without being limited to the example embodiments described above. Other embodiments can be formed by combining elements in different embodiments.

Here, the various example embodiments included in the present disclosure are described in [E1] to [E19] below.

[E1] An etching method comprising:
(a) supplying a film forming gas into a chamber through a gas feeding port of a showerhead containing silicon to form a protective film on an inner wall of the gas feeding port; and
(b) supplying an etching gas into the chamber through the gas feeding port on which the protective film is formed to etch a substrate in the chamber with plasma generated from the etching gas.

According to the method [E1], in (b), the inner wall of the gas feeding port can be protected by the protective film.

[E2] The etching method according to claim 1, further comprising:
(c) providing the substrate in the chamber between (a) and (b).

In this case, it is possible to suppress the substrate from being exposed to the film forming gas.

[E3] The etching method according to claim 1 or 2,
wherein a temperature of the showerhead in (a) is higher than a temperature of the showerhead in (b).

In this case, formation of the protective film is promoted in (a), but the protective film is difficult to remove in (b).

[E4] The etching method according to claim 1 or 2,
wherein the protective film contains a metal.

[E5] The etching method according to claim 4,
wherein the film forming gas contains a metal fluoride gas.

[E6] The etching method according to claim 5,
wherein the protective film contains tungsten, and

the film forming gas contains a tungsten hexafluoride gas.

[E7] The etching method according to claim 5,
wherein the protective film contains molybdenum, and
the film forming gas contains a molybdenum hexafluoride gas.

[E8] The etching method according to claim 1 or 2,
wherein in (a), no plasma is generated in the chamber.

[E9] The etching method according to claim 1 or 2, further comprising:
(d) removing a silicon oxide film formed on a surface of the showerhead before (a).

[E10] The etching method according to claim 9,
wherein the silicon oxide film is removed by a hydrogen fluoride gas.

[E11] The etching method according to claim 1 or 2,
wherein the etching gas contains a metal fluoride gas.

[E12] The etching method according to claim 1 or 2,
wherein the protective film has a thickness of 100 nm or more and 10μm or less.

[E13] The etching method according to claim 1 or 2,
wherein a flow rate of the film forming gas is greater than a flow rate of the etching gas.

In this case, the protective film can be made thicker.

[E14] The etching method according to claim 1 or 2,
wherein the showerhead constitutes at least a part of a ceiling of the chamber, and
in (a), the protective film is also formed on a lower surface of the showerhead.

[E15] The etching method according to claim 14,
wherein the protective film has a first thickness on the inner wall of the gas feeding port and has a second thickness smaller than the first thickness on the lower surface.

[E16] The etching method according to claim 1 or 2, further comprising:
(e) forming a precoat on an inner wall of the chamber before (b).

[E17] The etching method according to claim 16,
wherein (e) is performed between (a) and (b).

[E18] The etching method according to claim 16,
wherein the precoat contains carbon.

[E19] A plasma processing apparatus comprising:
a showerhead containing silicon and having a gas feeding port;
a chamber;
a substrate support for supporting a substrate in the chamber;
a gas supply configured to supply a film forming gas and an etching gas into the chamber through the gas feeding port;
a plasma generator configured to generate plasma from the etching gas in the chamber; and
a controller configured to control the plasma processing apparatus to perform an etching method,
wherein the etching method includes
   (a) supplying the film forming gas into the chamber through the gas feeding port of the showerhead to form a protective film on an inner wall of the gas feeding port, and
   (b) supplying the etching gas into the chamber through the gas feeding port on which the protective film is formed to etch the substrate in the chamber with the plasma generated from the etching gas.

From the foregoing description, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. An etching method comprising:
supplying a film forming gas into a chamber through a gas feeding port of a showerhead including silicon to form a protective film on an inner wall of the gas feeding port; and
supplying an etching gas into the chamber through the gas feeding port on which the protective film is formed to etch a substrate in the chamber with plasma generated from the etching gas.

2. The etching method according to claim 1, further comprising:
providing the substrate in the chamber between the supplying a film forming gas and the supplying an etching gas.

3. The etching method according to claim 1, wherein
a temperature of the showerhead in the supplying a film forming gas is higher than a temperature of the showerhead in the supplying an etching gas.

4. The etching method according to claim 1, wherein
the protective film includes a metal.

5. The etching method according to claim 4, wherein
the film forming gas includes a metal fluoride gas.

6. The etching method according to claim 5, wherein
the protective film includes tungsten, and
the film forming gas includes a tungsten hexafluoride gas.

7. The etching method according to claim 5, wherein
the protective film includes molybdenum, and
the film forming gas includes a molybdenum hexafluoride gas.

8. The etching method according to claim 1, wherein
in the supplying a film forming gas, no plasma is generated in the chamber.

9. The etching method according to claim 1, further comprising:
removing a silicon oxide film formed on a surface of the showerhead before the supplying a film forming gas.

10. The etching method according to claim 9, wherein
the silicon oxide film is removed by a hydrogen fluoride gas.

11. The etching method according to claim 1, wherein
the etching gas includes a metal fluoride gas.

12. The etching method according to claim 1, wherein
the protective film has a thickness of from 100 nm to 10 μm.

13. The etching method according to claim 1, wherein
a flow rate of the film forming gas is greater than a flow rate of the etching gas.

14. The etching method according to claim 1, wherein
the showerhead is at least a part of a ceiling of the chamber, and
in the supplying a film forming gas, the protective film is also formed on a lower surface of the showerhead.

15. The etching method according to claim 14, wherein
the protective film has a first thickness on the inner wall of the gas feeding port and has a second thickness smaller than the first thickness on the lower surface.

16. The etching method according to claim 1, further comprising:
forming a precoat on an inner wall of the chamber before the supplying an etching gas.

17. The etching method according to claim 16, wherein
the forming a precoat is performed between the supplying a film forming gas and the supplying an etching gas.

18. The etching method according to claim 16, wherein
the precoat includes carbon.

19. A plasma processing apparatus comprising:
a showerhead including silicon and having a gas feeding port;
a chamber;
a substrate support configured to support a substrate in the chamber;
a gas supply configured to supply a film forming gas and an etching gas into the chamber through the gas feeding port;
a plasma generator configured to generate plasma from the etching gas in the chamber; and
a circuitry configured to control the plasma processing apparatus to perform an etching method,
wherein the etching method includes
supplying the film forming gas into the chamber through the gas feeding port of the showerhead to form a protective film on an inner wall of the gas feeding port, and
supplying the etching gas into the chamber through the gas feeding port on which the protective film is formed to etch the substrate in the chamber with the plasma generated from the etching gas.
